(19) United States
(12) Patent Application Publication
(10) Pub. No.: US 2013/0308393 A1
(43) Pub. Date: Nov. 21, 2013

(54) NON-VOLATILE MEMORY DEVICE AND METHOD FOR DRIVING THE SAME

(71) Applicant: Tae-Un YOUN, Gyeonggi-do (KR)

(72) Inventor: Tae-Un YOUN, Gyeonggi-do (KR)

(21) Appl. No.: 13/605,775

(22) Filed: Sep. 6, 2012

(30) Foreign Application Priority Data
May 21, 2012 (KR) 10-2012-0053756

(51) Int. Cl. G11C 7/10; G11C 7/00

(52) U.S. Cl. 365/189.05; 365/189.011

(57) ABSTRACT

A non-volatile memory device includes a memory cell block programmed with data, a page buffer block configured to perform a program verification operation for verifying the data on a verification target memory cell as many times as a predetermined number, and temporarily store a plurality of verification result data obtained from every program verification operation, a comparison block configured to compare the multiple verification result data, which are temporarily stored in the page buffer block, with each other to produce a comparison result, and a control block configured to determine whether a program operation is performed again on the verification target memory cell based on the comparison result.

### CROSS-REFERENCE TO RELATED APPLICATIONS

The present application claims priority of Korean Patent Application No. 10-2012-0053756, filed on May 21, 2012, which is incorporated herein by reference in its entirety.

### BACKGROUND

1. Field

Exemplary embodiments of the present invention relate to a design technology of semiconductor devices, and more particularly, to a non-volatile memory device and a method for driving the same.

2. Description of the Related Art

Non-volatile memory devices, which are a kind of semiconductor memory devices, generally retain stored data although power supply is cut off. A memory cell in a non-volatile memory device is programmed with a data through a program operation. During the program operation, the threshold voltage of the memory cell is changed. The level of the threshold voltage of the memory cell is different according to the stored or programmed data in the memory cell. Recently, a program method for programming a data of more than two bits in one memory cell unit has been developed.

In an operation, the threshold voltage of a memory cell may rise higher than a target voltage level. Although memory cells store the same data, the threshold voltage of each of the memory cell may be different a little bit so that the threshold voltages of the memory cells are distributed within a predetermined range. If the distribution range of the threshold voltages of the memory cells is broad, the stored data in the memory cells cannot be read out accurately.

An Incremental Step Pulse Programming (ISSP) method has been developed to narrow the distribution range of the threshold voltages of memory cells. According to the ISPP method, memory cells are programmed by applying a program voltage for each program loop. The program state is verified by comparing the threshold voltages of the memory cells with a verification voltage. The program operation is repeatedly performed by applying a program voltage, which is increased by a predetermined step, into some memory cells having a threshold voltage which is lower than the verification voltage. The program operation ends for other memory cells having threshold voltage which increases up to the verification voltage.

As the size of memory cells decreases, interference between the memory cells becomes serious. Even though the memory cells are programmed in the ISPP method, there is limitation in narrowing the distribution range of the threshold voltages of the memory cells.

To overcome the limitation, a method of performing a double verification operation by using two verification voltages for each program loop in the verification process for verifying the program state of each memory cell is suggested. In other words, the ISPP method including the double verification operation is suggested.

According to the double verification operation, the threshold voltages of the memory cells are detected twice by using a target verification voltage and a temporary verification voltage that is lower than the target verification voltage while the selected memory cells are in a program state. Then, the memory cells are divided into: first memory cells whose threshold voltages are lower than the temporary verification voltage; second memory cells whose threshold voltages are higher than the temporary verification voltage but lower than the target verification voltage; and third memory cells whose threshold voltages are higher than the target verification voltage based on the threshold voltage detection results. The first and second memory cells whose threshold voltages are lower than the target verification voltage are programmed again with a program voltage that is higher than the program voltage used in the program operation. When the first and second memory cells are programmed again, the threshold voltages of the second memory cells may be prevented from increasing higher than the target verification voltage by applying approximately 0V to bit lines coupled with the first memory cells and applying a voltage, which is higher than approximately 0V but lower than a power source voltage VCC, to other bit lines coupled with the second memory cells. This is because the incremental extent of the threshold voltages of the second memory cells is decreased. Accordingly, the selected memory cells may be programmed to have their threshold voltages with a narrow distributed range.

As the sizes of non-volatile memory devices decrease recently, Random Telegraph Noise (RTN) becomes an important issue. The RTN refers to a phenomenon that electrons emit from a border trap or electrons are captured by a border trap.

FIGS. 1A to 1C illustrate RTN occurring in a memory cell.

Referring to FIGS. 1A to 1C, a border trap is formed between a silicon substrate and a gate electrode that constitute a memory cell. Electrons are emitted from or captured by the border trap between the silicon substrate and the gate (see FIGS. 1A and 1B). As electrons are emitted from or captured by the border trap between the silicon substrate and the gate, the threshold voltage Vₜₕ of the memory cell is changed (see FIG. 1C).

When the threshold voltage Vₜₕ of memory cell is changed, the memory cell may be recognized as a programmed memory cell although the program operation to the memory cell is not finished yet. This phenomenon may be called “under program.” When the under program phenomenon occurs, an erroneous data may be read out during a read operation.

### SUMMARY

An embodiment of the present invention is directed to a non-volatile memory device that may be capable of preventing under program phenomenon caused by Random Telegraph Noise (RTN), and a method for operating the non-volatile memory device.

In accordance with an embodiment of the present invention, a non-volatile memory device includes: a memory cell block programmed with data; a page buffer block configured to perform a program verification operation for verifying the data on a verification target memory cell as many times as a predetermined number, and temporarily store a plurality of verification result data obtained from in every program verification operation; a comparison block configured to compare the multiple verification result data, which are temporarily stored in the page buffer block, with each other to produce a comparison result; and a control block configured to determine whether a program operation is performed again on the verification target memory cell based on the comparison result.

In accordance with another embodiment of the present invention, a non-volatile memory device includes: a first memory cell string coupled with a first bit line and including a plurality of memory cells; a first latch configured to temporarily store a first verification result data obtained from a first program verification operation that is performed on a verification target memory cell among the multiple memory cells; a second latch configured to temporarily store a second verification result data obtained from a second program verification operation that is performed on the verification target memory cell; a comparator configured to compare the first verification result data with the second verification result data to produce a comparison result; and a controller configured to perform a control to perform a program operation on the verification target memory cell based on the comparison result.

In accordance with yet another embodiment of the present invention, a method for operating a non-volatile memory device includes: programming data in a memory cell block; performing verification operations many times at a target memory cell in the memory cell block; comparing verification result data obtained from every verification operation with each other; and deciding whether to reprogram the target memory cell or not based on the comparison result.

### BRIEF DESCRIPTION OF THE DRAWINGS

FIGS. 1A to 1C illustrate Random Telegraph Noise (RTN) occurring in a memory cell.

FIG. 2 is a block diagram illustrating a non-volatile memory device in accordance with an embodiment of the present invention.

FIG. 3 is a block diagram illustrating a page buffer block and a first comparison block shown in FIG. 2.

FIG. 4 is an internal circuit diagram illustrating a page buffer of the page buffer block shown in FIG. 3.

FIG. 5 is a timing diagram describing a method for driving a non-volatile memory device in accordance with an embodiment of the present invention.

FIG. 6 is a timing diagram describing a program verification duration shown in FIG. 5.

FIG. 7 is a flowchart describing a method for operating the non-volatile memory device shown in FIGS. 5 and 6.

FIG. 8 is a table describing the comparison condition of FIG. 7.

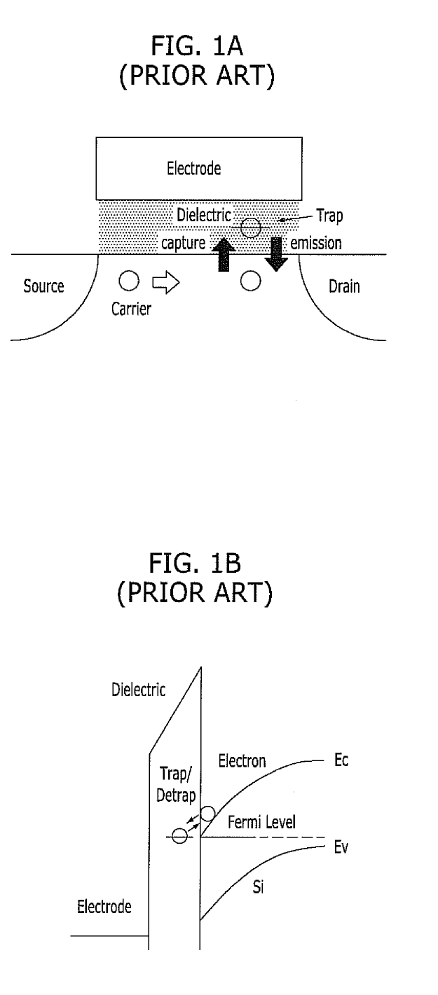

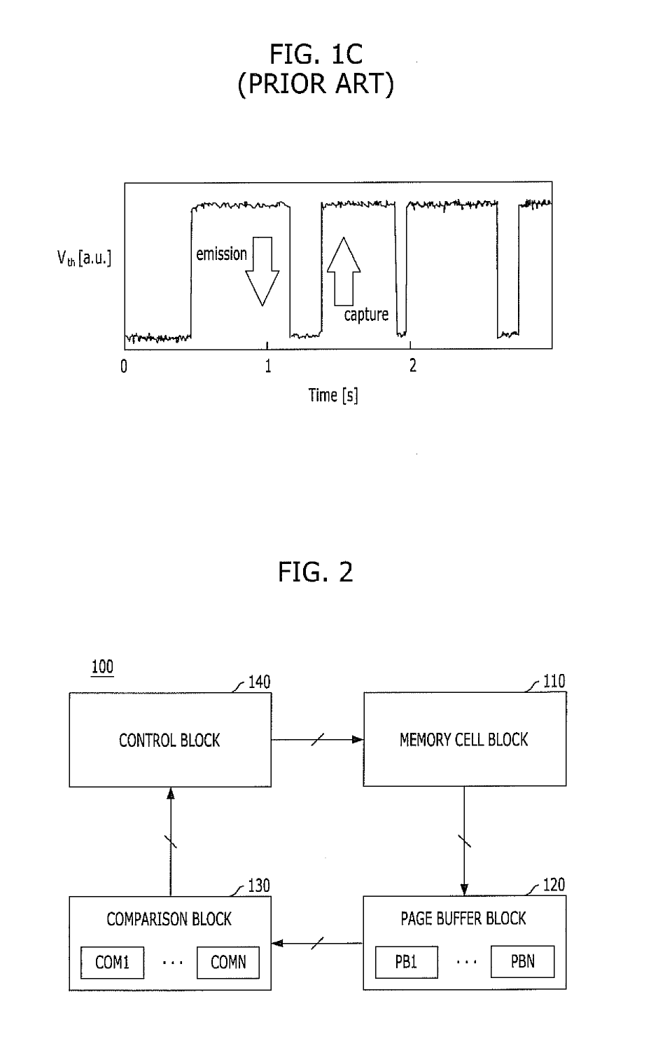

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

FIG. 2 is a block diagram illustrating a non-volatile memory device in accordance with an embodiment of the present invention.

Referring to FIG. 2, the non-volatile memory device 100 includes a memory cell block 110, a page buffer block 120, a comparison block 130, and a control block 140. The memory cell block 110 includes a plurality of cell strings, each including a plurality of memory cells coupled in series. The memory cell block 110 is programmed with data. The page buffer block 120 repeatedly performs a program verification operation for verifying the data programmed in the memory cell block 110 on a verification target memory cell as many times as a predetermined number. The page buffer block 120 temporarily stores a plurality of verification result data that are generated from the repeated program verification operation. The plurality of verification result data has the same value or different values, according to a program state of the memory cell block 110. The comparison block 130 compares the verification result data, which are temporarily stored in the page buffer block 120, with each other. The control block 140 performs a control to resume the program operation on the verification target memory cell based on the comparison result of the comparison block 130. For example, if the comparison result shows that the plurality of verification result data has the same value, the control block 140 stop reprogram operation to the memory cell block 110.

The control block 140 decides whether to re-program the verification target memory cell based on the comparison result of the comparison block 130 after the program operation. The control block 140 controls the overall operations for programming a data in the memory cell block 110. For example, although not illustrated in detail in the drawing, the control block 140 includes an X decoder, a Y decoder, a voltage generator, and a control logic. The X decoder selectively enables a plurality of page buffers included in the page buffer block 120. The Y decoder selectively enables a plurality of word lines coupled with the memory cell block 110. The voltage generator generates diverse levels of voltages for a program operation, a verification operation, and a read operation. The control logic controls the overall operations of the X decoder, the Y decoder, and the voltage generator.

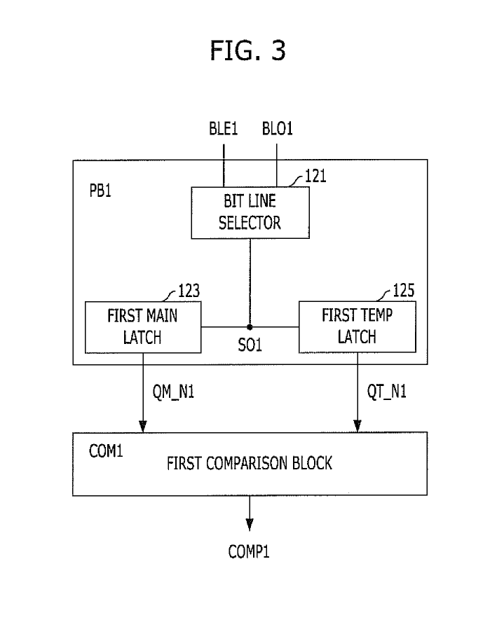

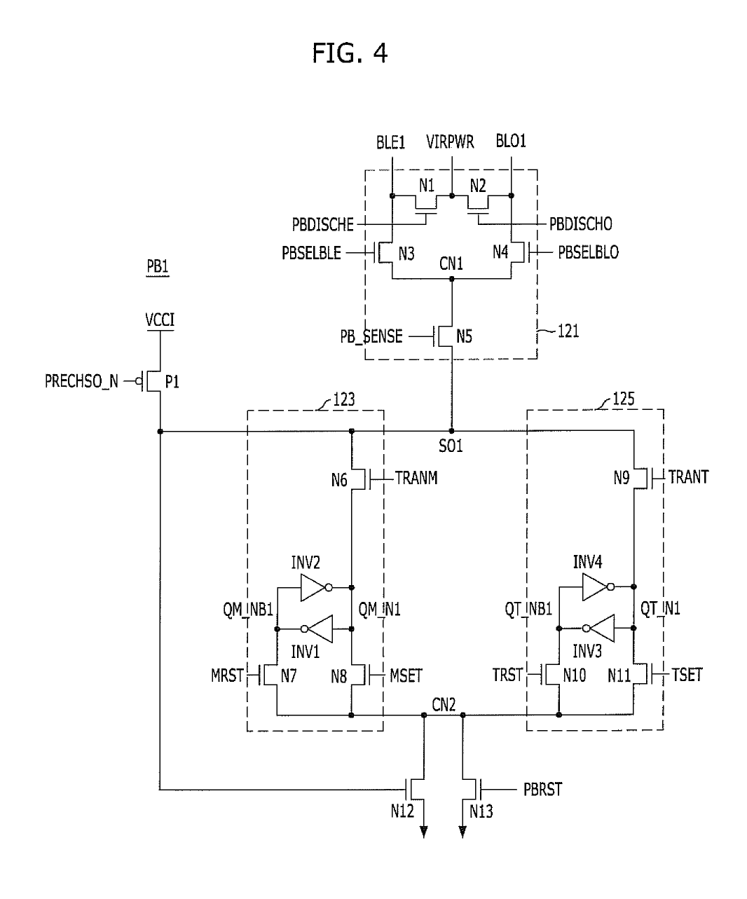

FIG. 3 is a block diagram illustrating the page buffer block 120 and the comparison block 130. FIG. 4 is an internal circuit diagram illustrating one page buffer included in the page buffer block 120.

In this embodiment, a first page buffer PB1 and a first comparison block COM1 coupled with the first page buffer PB1 are representatively described. The first page buffer PB1 shares a first bit line BLE1, which is coupled with a first cell string among even-numbered bit lines, and a second bit line BLO1 which is coupled with a second cell string and disposed adjacent to the first bit line BLE1 among odd-numbered bit lines. The first comparison block COM1 is coupled with the first page buffer PB1.

Referring to FIG. 3, the first page buffer PB1 includes a bit line selector 121, a first main latch 123, and a first temp latch 125. The bit line selector 121 selectively couples a sensing node SO1 with any one of the first bit line BLE1 and the second bit line BLO1. The first main latch 123 is coupled with the sensing node SO1. The first main latch 123 temporarily stores a first verification result data QM_N1 of a first program verification operation performed on the verification target memory cell among the memory cells in the first and second cell strings. The first temp latch 125 is coupled with the sensing node SO1. The first temp latch 125 temporarily stores a second verification result data QT_N1 of a second program verification operation performed on the verification target memory cell among the memory cells in the first and second cell strings. The second program verification operation is performed following the first program verification operation.

For example, referring to FIG. 4, the bit line selector 121 includes first and second NMOS transistors N1 and N2, third and fourth NMOS transistors N3 and N4, and a fifth NMOS transistor N5. The first and second NMOS transistors N1 and N2 are serially coupled between the first bit line BLE1 and the second bit line BLO1. The first and second NMOS transistors N1 and N2 apply a bias voltage VIRPWR to the first bit line BLE1 and the second bit line BLO1 in response to discharge signals PBDISCHE and PBDISCHO, respectively. The third and fourth NMOS transistors N3 and N4 are coupled between the first and second bit lines BLE1 and BLO1 and a first common node CN1. The third and fourth NMOS transistors N3 and N4 selectively couple the first and second bit lines BLE1 and BLO1 with the first common node CN1 in response to first and second bit line selection signals PBSELBLE and PBSELBLO, respectively. The fifth NMOS transistor N5 couples the first common node CN1 with the sensing node SO1 in response to a sensing signal PB_SENSE.

The first main latch 123 includes first and second inverters INV1 and INV2, a sixth NMOS transistor N6, a seventh NMOS transistor N7, and an eighth NMOS transistor N8. The first and second inverters INV1 and INV2 are coupled in parallel in a reverse direction between a first latch node QM_N1 and a first inverse latch node QM_NB1 to form a latch structure. The sixth NMOS transistor N6 couples the sensing node SO1 with the first latch node QM_N1 in response to a first transmission signal TRANM. The seventh NMOS transistor N7 couples the first inverse latch node QM_NB1 with a second common node CN2 in response to a first main control signal MRST. The eighth NMOS transistor N8 couples the first latch node QM_N1 with the second common node CN2 in response to a second main control signal MSET.

The first temp latch 125 includes third and fourth inverters INV3 and INV4, a ninth NMOS transistor N9, a tenth NMOS transistor N10, and an eleventh NMOS transistor N11. The third and fourth inverters INV3 and INV4 are coupled in parallel in a reverse direction between a second latch node QT_N1 and a second inverse latch node QT_NB1 to form a latch structure. The ninth NMOS transistor N9 couples the sensing node SO1 with the second latch node QT_N1 in response to a second transmission signal TRANT. The tenth NMOS transistor N10 couples the second inverse latch node QT_NB1 with the second common node CN2 in response to a first temp control signal TRST. The eleventh NMOS transistor N11 couples the second latch node QT_N1 with the second common node CN2 in response to a second temp control signal TSET. Although this embodiment illustrates the first page buffer PB1 including the first main latch 123 and the first temp latch 125, the first page buffer PB1 may further include diverse latches such as another latch for latching a data to be programmed.

The first page buffer PB1 may further include a first PMOS transistor P1, a twelfth NMOS transistor N12, and a thirteenth NMOS transistor N13. The first PMOS transistor P1 precharges the sensing node SO1 with a predetermined voltage VCCI in response to a precharge control signal PRECHSO_N. The twelfth NMOS transistor N12 selectively couples the second common node CN2 with a ground voltage terminal according to the voltage level of the sensing node SO1. The thirteenth NMOS transistor N13 selectively couples the second common node CN2 with the ground voltage terminal in response to an initialization signal PBRST.

Referring back to FIG. 3, the first comparison block COM1 compares the first verification result data QM_N1 with the second verification result data QT_N1 that are latched to the first page buffer PB1. When the first verification result data QM_N1 and the second verification result data QT_N1 have information corresponding to verification pass, the first comparison block COM1 outputs a first comparison signal COM_PB1 for terminating the program operation to the control block 140. On the other hand, when the first comparison block COM1 shows that at least any one between the first verification result data QM_N1 and the second verification result data QT_N1 has information corresponding to program verification result verification failure, the first comparison block COM1 outputs a first comparison signal COM_PB1 for performing a reprogram operation to the control block 140.

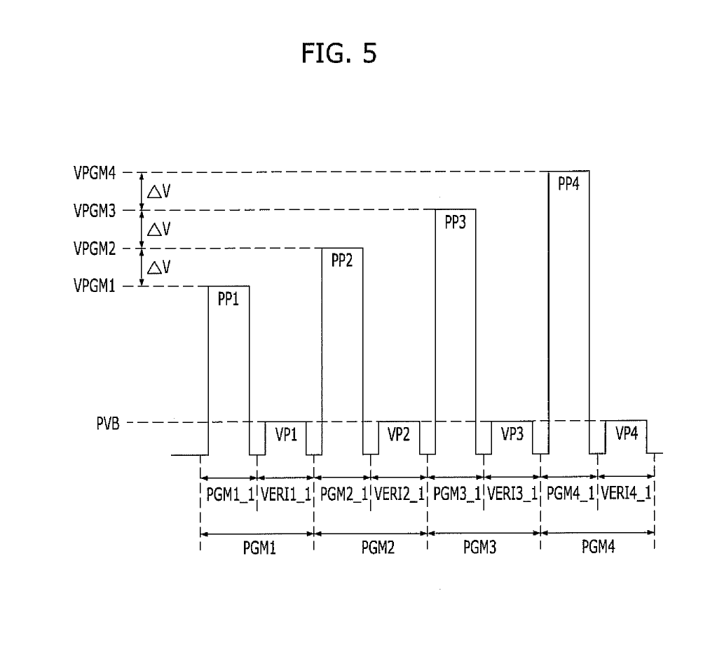

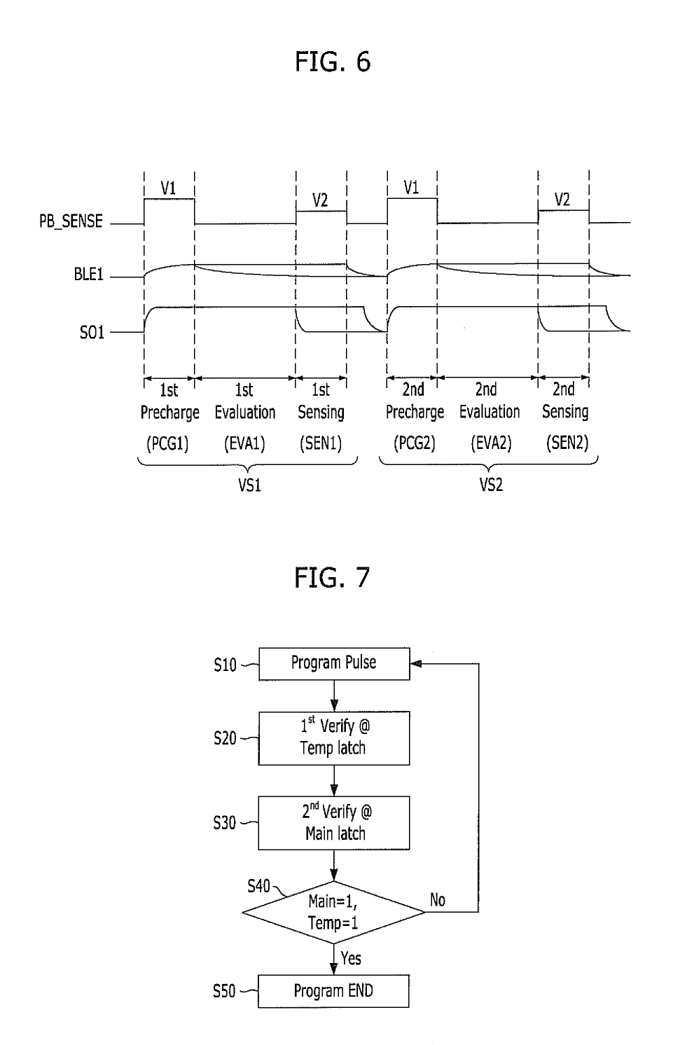

Hereafter, an operation of the non-volatile memory device 100 in accordance with the embodiment of the present invention is described with reference to FIGS. 5 and 6.

FIG. 5 is a timing diagram describing a method for driving the non-volatile memory device 100 in accordance with an embodiment of the present invention. FIG. 6 is a timing diagram describing a program verification duration shown in FIG. 5.

Referring to FIG. 5, the non-volatile memory device 100 includes program durations PGM1_1, PGM2_1, PGM3_1, PGM4_1, and the like, and program verification durations VERI1_1, VERI2_1, VERI3_1, VERI4_1, and the like, for each program loop PGM1, PGM2, PGM3, PGM4, and the like. The non-volatile memory device 100 includes an Incremental Step Pulse Programming (ISPP) scheme where a program operation is performed by increasing the voltage level of program pulses PP1, PP2, PP3, PP4, and the like by a predetermined step ΔV and is used in the program loops PGM1, PGM2, PGM3, PGM4, and the like.

To be more specific, a program operation is performed on memory cells (which are referred to as verification target memory cells) that are selected by applying the first program pulse PP1. The verification target memory cells whose threshold voltage Vₜₕ is higher than a verification voltage PVB when a first verification voltage VP1 is applied are allowed to pass. Meanwhile, memory cells having threshold voltage Vₜₕ, which is not higher than the verification voltage PVB, are reprogrammed by applying the second program pulse PP2. Herein, the memory cells of the verification target memory cells are prevented from being programmed again when their threshold voltage Vₜₕ is higher than the verification voltage PVB. Accordingly, over-programming is prevented.

Subsequently, even after a program operation is performed by applying the second program pulse PP2, the threshold voltage Vₜₕ of the memory cells that are not allowed to pass among the verification target memory cells is compared with the verification voltage PVB to decide whether to be allowed to pass or not. Such a program operation and a verification operation are repeatedly performed by gradually increasing VPGM3, VPGM4, and the like the voltage levels of the program pulses PP3, PP4, and the like until all the verification target memory cells are programmed.

Meanwhile, each of program verification durations VERI1_1, VERI2_1, VERI3_1, VERI4_1, and the like includes two verification processes. In other words, as illustrated in FIG. 6, each of program verification durations VERI1_1, VERI2_1, VERI3_1, VERI4_1, and the like includes a first program verification process VS1 and a second program verification process VS2. Each of the first program verification process VS1 and the second program verification process VS2 includes a precharge step, an evaluation step, and a sensing step. The precharge step PCG1 and PCG2 precharges the first bit line BLE1 or the second bit line BLO1 coupled with the verification target memory cells with a predetermined voltage. The evaluation step EVA1 and EVA2 changes a voltage of one of the first bit line BLE1 and the second bit line BLO1, which is precharged during the precharge step PCG1 and PCG2, after the precharge step PCG1 and PCG2 is finished and the verification target memory cells are programmed. The sensing step SEN1 and SEN2 senses the voltage of one of the first bit line BLE1 and the second bit line BLO1 to store either the first verification result data QM_N1 corresponding to the sensed voltage in the first main latch 123 or the second verification result data QT_N1 in the first temp latch 125 when the evaluation step EVA1 and EVA2 is finished.

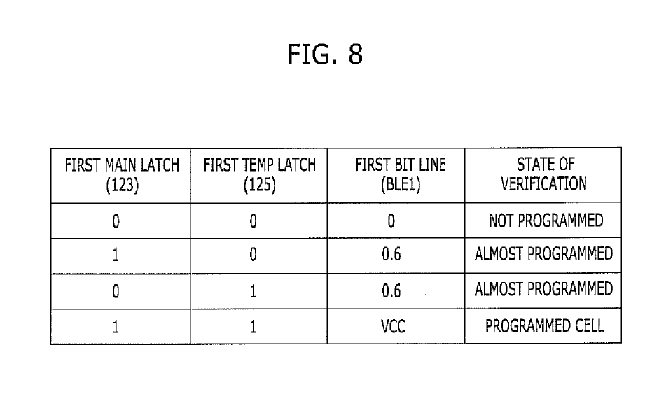

FIG. 7 is a flowchart describing a method for driving the non-volatile memory device 100 shown in FIGS. 5 and 6. FIG. 8 is a table describing the comparison condition of FIG. 7.

Referring to FIG. 7, the non-volatile memory device 100 may proceed the program loops PGM1, PGM2, PGM3, PGM4, and the like, where the program duration PGM1_1, PGM2_1, PGM3_1, PGM4_1, and the like. is repeated based on the verification result of every program verification duration VERI1_1, VERI2_1, VERI3_1, VERI4_1, and the like, until all the verification target memory cells are programmed.

In other words, the program loops PGM1, PGM2, PGM3, PGM4, and the like. includes a program step, a first program verification step, a second program verification step, and a comparison step. The program step S10 is for programming data in selected memory cells by applying the first program pulse PP1. The first program verification step S20 is for sensing the first verification result data QM_N1 corresponding to the program state of the verification target memory cells, while a first verification voltage VP1 is applied to word lines coupled with the verification target memory cells, and temporarily storing the first verification result data QM_N1 in the first main latch 123. The second program verification step S30 is for sensing the second verification result data QT_N1 corresponding to the program state of the verification target memory cells, while the first verification voltage VP1 is applied to word lines coupled with the verification target memory cells, and temporarily storing the second verification result data QT_N1 in the first temp latch 125. The comparison step S40 is for comparing the first verification result data QM_N1 and the second verification result data QT_N1, which are temporarily stored in the first main latch 123 and the first temp latch 125, to decide whether the verification target memory cells are programmed again or not based on the comparison result.

In the comparison step S40, as illustrated in FIG. 8, a comparison signal for terminating the program operation is outputted when both of the first verification result data QM_N1 and the second verification result data QT_N1, which are temporarily stored in the first main latch 123 and the first temp latch 125, include information representing verification pass, e.g., information of a logic high level. On the other hand, a comparison signal for performing a reprogram operation is outputted in the comparison step S40, when at least any one between the first verification result data QM_N1 and the second verification result data QT_N1, which are temporarily stored in the first main latch 123 and the first temp latch 125, include information representing verification failure, e.g., information of a logic low level. When the reprogram operation is performed, the program step S10, the first program verification step S20, the second program verification step S30, and the comparison step S40 are sequentially performed.

According to the embodiment, the influence of Random Telegraph Noise (RTN) occurring in a memory cell may be minimized. Therefore, the reliability of a program verification operation may be improved.

Since the under program phenomenon based on the Random Telegraph Noise (RTN) is not likely to occur more than two consecutive times in terms of probability, the under program phenomenon may be controlled by performing a program verification operation more than twice and minimizing the Random Telegraph Noise (RTN).

While the present invention has been described with respect to the specific embodiments, it will be apparent to those skilled in the art that various changes and modifications may be made without departing from the spirit and scope of the invention as defined in the following claims.

For example, although the embodiment embodies two latches to perform a program verification process twice for each program loop, the scope and spirit of the present invention are not limited to it. More than three latches may be embodied. The program verification process may be performed more than three times for each program loop.

Also, although the embodiment includes a precharge step, an evaluation step, and a sensing step for each program verification process, the scope and spirit of the present invention are not limited to it, Many known and developed program verification processes may be applied to the technology of the present invention.

Also, although the embodiment of the present invention exemplarily describes a structure where two neighboring bit lines share one page buffer, the scope and spirit of the present invention are not limited to it, and the technology of the present invention may be applied to all structures where page buffers and bit lines correspond in one-on-one or in one-to-multiple number as well.

What is claimed is:

1. A non-volatile memory device, comprising:
a memory cell block programmed with data;
a page buffer block configured to perform a program verification operation for verifying the data on a verification target memory cell as many times as a predetermined number, and temporarily store a plurality of verification result data obtained from every program verification operation;
a comparison block configured to compare the multiple verification result data, which are temporarily stored in the page buffer block, with each other to produce a comparison result; and
a control block configured to determine whether a program operation is performed again on the verification target memory cell, based on the comparison result.

2. The non-volatile memory device of claim 1, wherein the control block controls overall operations for programming the data in the memory cell block, and after a program operation is performed, the control block decides whether to reprogram the verification target memory cell or not based on the comparison result.

3. The non-volatile memory device of claim 2, wherein the control block controls the program operation based on an Incremental Step Pulse Programming (ISPP).

4. A non-volatile memory device comprising:
a first memory cell string coupled with a first bit line and including a plurality of memory cells;
a first latch configured to temporarily store a first verification result data obtained from a first program verification operation that is performed on a verification target memory cell among the multiple memory cells;
a second latch configured to temporarily store a second verification result data obtained from a second program verification operation that is performed on the verification target memory cell;
a comparator configured to compare the first verification result data with the second verification result data to produce a comparison result; and
a controller configured to perform a control to perform a program operation on the verification target memory cell based on the comparison result.

5. The non-volatile memory device of claim 4, wherein the second program verification operation is performed following the first program verification operation.

6. The non-volatile memory device of claim 4, wherein the controller controls overall operations for programming the data in the multiple memory cells, and after a program operation is performed, the controller decides whether to reprogram the verification target memory cell or not based on the comparison result.

7. The non-volatile memory device of claim 6, wherein the controller controls the program operation based on an Incremental Step Pulse Programming (ISPP).

8. The non-volatile memory device of claim 4, further comprising:
a second memory cell string coupled with a second bit line and including a plurality of memory cells; and
a bit line selector configured to selectively couple one between the first bit line and the second bit line with a sensing node,
where the first latch and the second latch are coupled with the sensing node.

9. A method for operating a non-volatile memory device, comprising:
programming data in a memory cell block;
performing verification operations many times at a target memory cell in the memory cell block;
comparing verification result data obtained from every verification operation with each other; and
deciding whether to reprogram the target memory cell or not based on the comparison result.

10. The method of claim 9, wherein performing verification operations includes:
sensing a first verification result data corresponding to the program state of the target memory cell while a predetermined verification voltage is applied to a word line coupled with the target memory cell included in the memory cell block, and temporarily storing the first verification result data in a first latch; and
sensing a second verification result data corresponding to the program state of the target memory cell while the predetermined verification voltage is applied to the word line coupled with the target memory cell, and temporarily storing the second verification result data in a second latch.

11. The method of claim 10, wherein each of the sensing of the first verification result data and the sensing of the second verification result data includes:
precharging the bit line coupled with the target memory cell with a predetermined voltage;
when the precharging of the bit line coupled with the target memory cell with the predetermined voltage ends, changing the precharge voltage of the bit line based on the program state of the target memory cell; and
when the changing of the precharge voltage of the bit line based on the program state of the target memory cell ends, sensing the changed voltage of the bit line and storing the first verification result data or the second verification result data that corresponds to the sensed voltage in the first latch or the second latch.

12. The method of claim 10, wherein the program operation ends, when both of the first verification result data and the second verification result data that are stored in the first latch and the second latch have information representing verification pass.

13. The method of claim 10, wherein a reprogram operation is performed, when at least one between the first verification result data and the second verification result data that are stored in the first latch and the second latch has information representing verification failure.

14. The method of claim 13, wherein the reprogram operation sequentially performs:
programming the data in the memory cell block;
sensing another first verification result data corresponding to the program state of the target memory cell while the predetermined verification voltage is applied to the word line coupled with the target memory cell included in the memory cell block, and temporarily storing the first verification result data in the first latch;
sensing another second verification result data corresponding to the program state of the target memory cell while the predetermined verification voltage is applied to the word line coupled with the target memory cell and temporarily storing the second verification result data in the second latch; and
comparing the first verification result data with the second verification result data; and
deciding whether to reprogram the target memory cell or not based on the comparison result.

15. The non-volatile memory device of claim 14, wherein the reprogram operation is performed based on an Incremental Step Pulse Programming (ISPP).
